(19) United States
(12) Patent Application Publication
(10) Pub. No.: US 2007/0234959 A1
(43) Pub. Date: Oct. 11, 2007

(54) Evaporation apparatus, evaporation method, method of manufacturing electro-optical device, and film-forming apparatus

(75) Inventors: Junji Nakanishi, Chino-shi (JP); Yuichi Shimizu, Hokuto-shi (JP)

Correspondence Address: ADVANTEDGE LAW GROUP, LLC, 3301 NORTH UNIVERSITY AVE., SUITE 200, PROVO, UT, 84604, US

(73) Assignee: Seiko Epson Corporation, Tokyo (JP)

(21) Appl. No.: 11/732,252

(22) Filed: Apr. 3, 2007

(30) Foreign Application Priority Data
Apr. 5, 2006 (JP) 2006-104428
Feb. 7, 2007 (JP) 2007-028421

(51) Int. Cl. C23C 16/00

(52) U.S. Cl. 118/720; 118/726

(57) ABSTRACT

An evaporation apparatus includes a deposition unit that deposits a substance to be evaporated from an evaporation source on a substrate, a vacuum tank that defines a space for placing the evaporation source and the substrate and maintains a vacuum state in the space, and an evaporated substance adhering unit that is provided in at least a portion of a wall in the vacuum tank and has a plurality of protrusions protruding in a direction toward the evaporation source at an angle relative to a direction normal to the wall, and to which the evaporated substance is adhered.

### BACKGROUND

1. Technical Field

The present invention relates to an evaporation apparatus that is suitably used for forming an inorganic alignment film in an electro-optical device, such as a liquid crystal device or the like, by oblique evaporation, to an evaporation method, to a method of manufacturing an electro-optical device using the evaporation apparatus, and a film-forming apparatus.

2. Related Art

In an evaporation apparatus, an evaporated substance from an evaporation source is adhered to an inner wall of a vacuum chamber, and the substance adhered to the inner wall is separated from the wall surface, which contaminates the inside of the vacuum chamber. In order to prevent this problem, a deposition preventing plate is provided at the inner wall of the vacuum chamber. For example, in JP-A-2001-192816, there is disclosed a technology that reduces the amount of the evaporated substance to be adhered to the deposition preventing plate by attaching a heater to the deposition preventing plate, thereby preventing the substance adhered to the inner wall from being separated. Further, in JP-A-6-181175, there is disclosed a technology that controls a release direction of the evaporated substance by providing a coolable shielding plate having an opening between the evaporation source and a substrate on which a film is to be formed.

However, in the above-described technologies, there is a technical problem in that it is difficult to sufficiently prevent the substance adhered to the deposition preventing plate provided at the inner wall of the vacuum chamber from being separated. Further, there is also a technical problem in that the directionality of the deposited film may be degraded by the evaporated substance rebounding from the inner wall of the vacuum chamber or the deposition preventing plate.

### SUMMARY

An advantage of some aspects of the invention is that it provides an evaporation apparatus that can prevent a substance adhered to an inner wall of a vacuum chamber from being separated and improve directionality of a deposited film, an evaporation method, a method of manufacturing an electro-optical device using the evaporation apparatus, and a film-forming apparatus.

According to a first aspect of the invention, an evaporation apparatus includes an evaporation unit that deposits a substance to be evaporated from an evaporation source on a substrate, a vacuum tank that defines a space for placing the evaporation source and the substrate and maintains a vacuum state in the space, and an evaporated substance adhering unit that is provided in at least a portion of a wall in the vacuum tank and has a plurality of protrusions protruding in a direction toward the evaporation source at an angle relative to a direction normal to the wall, and to which the evaporated substance is adhered.

According to the evaporation apparatus of the first aspect of the invention, the substance evaporated from the evaporation source is deposited on the substrate by the evaporation unit provided in the vacuum tank. Here, the term ‘vacuum tank’ according to the aspects denotes a concept including a box, such as a chamber that can define a space for placing the evaporation source (also referred to as a target) and the substrate on which the evaporated substance is deposited, and can maintain a vacuum state in the space. The shape, the material, and the like of the vacuum tank are not particularly limited as long as the concept is satisfied. However, in view of mechanical, physical, and chemical stabilities, preferred examples of the material constituting the vacuum tank include metals, steels, glass, and ceramics. The terms ‘vacuum state’ denotes a concept including a state of a space filled with a gas having a pressure lower than atmospheric pressure. Preferably, the term ‘vacuum state’ represents a state of a space in which the pressure is reduced from atmospheric pressure to the extent that impurities, such as oxygen and nitrogen, contained in the air do not affect the quality of a film when the evaporated substance is deposited on the substrate. The phrase ‘maintain a vacuum state’ denotes a concept including a state where the degree of vacuum is constantly stable or the degree of vacuum can be considered to be constant as a result of canceling out the amount of gas exhausted by an exhaust system, such as a rotary pump, a mechanical booster pump, an oil-diffusion pump, or a turbomolecular pump, and the amount of leakage of a gas in the vacuum tank. As the ‘evaporation unit’, for example, a resistance heating evaporation method, an electromagnetic heating evaporation method, or the like may be used. The term ‘evaporation source’ according to the aspects denotes a concept including substances that can be evaporated by heating. The material, the shape, and other physical properties of the evaporation source are not particularly limited as long as the concept is satisfied. For example, the evaporation source may be an inorganic material, such as SiO or SiO₂. Alternatively, the evaporation source may be an inorganic material that can be used as a material of an inorganic alignment film in an electro-optical device, such as a liquid crystal device or the like.

In particular, according to the above-described configuration, the evaporated substance adhering unit that has the plurality of protrusions protruding in the direction toward the evaporation source at an angle relative to the direction normal to the wall is provided in at least a portion of the wall of the vacuum tank. That is, for example, when the evaporation source is placed on the lower side of the vacuum tank and the substrate is placed on the upper side thereof, a plurality of protrusions are provided to protrude in the direction toward the evaporation source (that is, an obliquely downward direction) above the evaporation source at the side portion of the wall of the vacuum tank. The plurality of protrusions each have, for example, a width and a thickness of approximately several mm, and protrude in eave shapes in the direction toward evaporation source by approximately several mm. The plurality of protrusions are arranged, for example, in a lattice shape or strip shapes at the wall of the vacuum tank. Moreover, the plurality of protrusions may be provided in a deposition preventing plate that is provided at the wall of the vacuum tank and to which the evaporated substance is adhered. That is, the term ‘evaporated substance adhering unit’ according to the aspects denotes a concept including a deposition preventing plate having a plurality of protrusions.

With the evaporated substance adhering unit, the amount of the substance held on the wall when the substance evaporated from the evaporation source is adhered to the wall of the vacuum tank as an adhered substance (that is, the amount of the evaporated substance that can be adhered to the wall) can be increased. That is, a time for which the adhered substance is held on the wall can be increased. Usually, upon evaporation by the evaporation unit, if the amount of the evaporated substance adhered to the wall of the vacuum tank is increased, the evaporated substance may not be held on the wall. However, according to the above-described configuration, the adhered substance can be prevented from being separated from the wall. Therefore, the amount of particles produced due to the adhered substance being separated from the wall in the vacuum tank can be reduced. As a result, the quality of a deposited film to be deposited on the substrate can be improved.

With the evaporated substance adhering unit, the amount of the substance evaporated from the evaporation source that can be adhered to the wall of the vacuum tank can be increased (that is, trap efficiency for trapping the evaporated substance is increased). Accordingly, the amount of the evaporated substance that rebounds from the wall of the vacuum tank can be reduced or the evaporated substance can be prevented from rebounding. Therefore, the amount of the evaporated substance that rebounds from the wall of the vacuum tank and goes toward the substrate can be reduced or the evaporated substance can be prevented from rebounding and going toward the substrate. Specifically, the amount of the evaporated substance that is directed in directions other than a predetermined direction and goes toward the substrate can be reduced or the evaporated substance can be prevented from being directed in directions other than a predetermined direction and going toward the substrate. As a result, the directionality of a deposited film to be deposited on the substrate, for example, an inorganic alignment film having a predetermined pretilt angle, can be increased. That is, the deposited film can be almost or completely uniformly formed on the entire surface or a relatively wide region of the substrate.

As described above, according to the evaporation apparatus of the first aspect of the invention, with the evaporated substance adhering unit having the plurality of protrusions protruding in the direction toward the evaporation source, the amount of the substance evaporated from the evaporation source that can be adhered to the wall of the vacuum tank is increased. Therefore, the amount of particles produced due to the adhered substance being separated from the wall in the vacuum tank can be reduced. In addition, the directionality of the deposited film to be deposited on the substrate can be improved.

In the evaporation apparatus according to the first aspect of the invention, the evaporation source may be disposed at the bottom surface of the vacuum tank, and the plurality of protrusions may be arranged at a side portion of the wall in multiple lines along a direction crossing a direction normal to the bottom surface.

With this configuration, the plurality of protrusions are arranged at the side portion of the wall of the vacuum tank at predetermined intervals along the direction crossing the direction normal to the bottom surface. For example, the plurality of protrusions are arranged in multiple lines of stripe shapes. In this case, if the plurality of protrusions are reduced in size or the arrangement intervals thereof become narrower, the number of the plurality of protrusions that are formed at the side portion of the wall is increased, and thus the total surface area of the plurality of protrusions can be increased. Therefore, the amount of the evaporated substance that is adhered to the plurality of protrusions can be increased.

In the evaporation apparatus according to the first aspect of the invention, the evaporation source may be disposed at the bottom surface of the vacuum tank, and the plurality of protrusions may be formed at the side portion of the wall to extend along a direction crossing a direction normal to the bottom surface.

With this configuration, the plurality of protrusions are formed at the side portion of the wall to extend along the direction crossing the direction normal to the bottom surface, usually, formed at the side portion of the wall to extend from one side crossing the bottom surface to another side facing the side. That is, the plurality of eave-shaped protrusions that are formed at the side portion of the wall to extend along the bottom surface are arranged in the direction crossing the bottom surface. Therefore, the evaporated substance that flies from the evaporation source disposed at the bottom surface in the direction crossing the bottom surface can be reliably adhered to the wall.

In a case where the plurality of protrusions are formed at the side portion of the wall, the side portion of the wall may be adjacent to the bottom surface.

In this case, since the plurality of protrusions are formed relatively close to the evaporation source, the amount of the evaporated substance that is adhered to the plurality of protrusions can be increased.

According to a second aspect of the invention, an evaporation apparatus includes an evaporation unit that deposits a substance to be evaporated from an evaporation source on a substrate, a vacuum tank that defines a space for placing the substrate and the evaporation source and maintains a vacuum state in the space, and an evaporated substance adhering unit that is provided in at least a portion of a wall of the vacuum tank and has a plurality of concave portions to be depressed with respect to the evaporation source in a direction toward the evaporation source at an angle relative to a direction normal to the wall, and to which the evaporated substance is adhered.

According to the evaporation apparatus of the second aspect of the invention, similarly to the evaporation apparatus according to the first aspect of the invention, the substance evaporated from the evaporation source is deposited on the substrate in the vacuum tank.

In particular, according to the above-described configuration, the evaporated substance adhering unit that has the plurality of concave portions to be depressed with respect to the evaporation source in the direction toward the evaporation source at an angle relative to the direction normal to the wall is provided in at least a portion of the wall of the vacuum tank. That is, for example, when the evaporation source is placed on the lower side of the vacuum tank and the substrate is placed on the upper side thereof, a plurality of concave portions are provided to be depressed with respect to the evaporation source along the direction toward the evaporation source (that is, an obliquely downward direction) above the evaporation source at the side portion of the wall of the vacuum tank. The plurality of concave portions each have, for example, a width and a thickness of approximately several mm, and are depressed in the direction toward the evaporation source by approximately several mm. The plurality of concave portions are arranged, for example, in a lattice shape or strip shapes at the wall of the vacuum tank. Moreover, the plurality of concave portions may be provided in a deposition preventing plate that is provided at the wall of the vacuum tank and to which the evaporated substance is adhered. That is, the term ‘evaporated substance adhering unit’ according to the aspects denotes a concept including a deposition preventing plate having a plurality of concave portions.

According to the evaporation apparatus of the second aspect of the invention, with the evaporated substance adhering unit that has the plurality of concave portions to be depressed with respect to the evaporation source along the direction toward the evaporation source, similarly to the evaporation apparatus according to the first aspect of the invention, the amount of the substance evaporated from the evaporation source that can be adhered to the wall of the vacuum tank can be increased. Therefore, the amount of particles produced due to the adhered substance being separated from the wall in the vacuum tank can be reduced. In addition, the directionality of the deposited film to be deposited on the substrate can be improved.

In the evaporation apparatus according to the second aspect of the invention, a space that is defined by an inner surface of each of the plurality of concave portions may have a space extending along the direction toward the evaporation source.

With this configuration, the evaporated substance easily enters the plurality of concave portions, and thus the amount of the evaporated substance that is adhered to the inner surface of each of the plurality of concave portions can be increased.

In the evaporation apparatus according to the second aspect of the invention, the evaporation source may be disposed at the bottom surface of the vacuum tank, and the plurality of concave portions may be arranged at a side portion of the wall in multiple lines along the bottom surface.

With this configuration, the plurality of concave portions are arranged at the side portion of the wall of the vacuum tank along the bottom surface at predetermined intervals. For example, the plurality of concave portions are arranged in multiple lines of stripe shapes. In this case, if the plurality of concave portions are reduced in size or the arrangement intervals thereof become narrower, the number of the plurality of concave portions that are formed at the side portion of the wall is increased, and thus the total surface area of the plurality of concave portions can be increased. Therefore, the amount of the evaporated substance that is adhered to the plurality of concave portions can be increased.

In the evaporation apparatus according to the second aspect of the invention, the evaporation source may be disposed at the bottom surface, and the plurality of concave portions may be formed at the side portion of the wall to extend along a direction crossing a direction normal to the bottom surface.

With this configuration, the plurality of concave portions are formed at the side portion of the wall of the vacuum tank to extend along the bottom surface, usually, formed at the side portion of the wall to extend from a side crossing the bottom surface to another side facing the side. That is, the plurality of concave portions that are formed at the side portion of the wall to extend along the bottom surface are arranged in the direction crossing the bottom surface. Therefore, the evaporated substance that files from the evaporation source disposed at the bottom surface in the direction crossing the bottom surface can be reliably adhered to the wall.

In a case where the plurality of concave portions are formed at the side portion of the wall, the side portion of the wall may be adjacent to the bottom surface.

In this case, since the plurality of concave portions are formed relatively close to the evaporation source, the amount of the evaporated substance that is adhered to the plurality of concave portions can be increased.

According to a third aspect of the invention, an evaporation apparatus includes an evaporation unit that deposits a substance to be evaporated from an evaporation source on a substrate, a vacuum tank that defines a space for placing the substrate and the evaporation source and maintains a vacuum space in the space, and an evaporated substance adhering unit that is provided in at least a portion of a wall of the vacuum tank and has a mesh-shaped concavo-convex portion with respect to the wall, and to which the evaporated substance is adhered.

According to the evaporation apparatus of the third aspect of the invention, similarly to the evaporation apparatus according to the first or second aspect of the invention, the substance evaporated from the evaporation source is deposited on the substrate in the vacuum tank.

In particular, according to the above-described configuration, the evaporated substance adhering unit that has the mesh-shaped concavo-convex portion with respect to the wall and to which the evaporated substance is adhered is provided in at least a portion of the wall of the vacuum tank. That is, for example, when the evaporation source is placed on the lower side of the vacuum tank and the substrate is placed on the upper side thereof, the mesh-shaped concavo-convex portion is provided above the evaporation source at the side portion of the wall of the vacuum tank. The mesh-shaped concavo-convex portion is formed, for example, by arranging a plurality of metal lines, which are formed of a metal, such as aluminum or the like, and have a diameter of approximately 1 mm, on the wall to form a mesh of approximately 2 mm square. Alternatively, a mesh that is formed form a plurality of metal lines formed of a metal, such as aluminum or the like, may be attached to the wall. Moreover, the mesh-shaped concavo-convex portion may be provided in a deposition preventing plate that is provided at the wall of the vacuum tank and to which the evaporated substance is adhered. That is, the term ‘evaporated substance adhering unit’ according to the aspects denotes a concept including a deposition preventing plate having a mesh-shaped concavo-convex portion.

According to the evaporation apparatus of the third aspect of the invention, with the evaporated substance adhering unit that has the mesh-shaped concavo-convex portion with respect to the wall, similarly to the evaporation apparatus according to the first aspect of the invention, the amount of the substance evaporated from the evaporation source that can be adhered to the wall of the vacuum tank can be increased. Therefore, the amount of particles produced due to the adhered substance being separated from the wall in the vacuum tank can be reduced. In addition, the directionality of the deposited film to be deposited on the substrate can be improved.

According to a fourth aspect of the invention, an evaporation apparatus includes an evaporation unit that deposits a substance to be evaporated from an evaporation source on a substrate, a vacuum tank that defines a space for placing the substrate and the evaporation source and maintains a vacuum state in the space, and an evaporated substance adhering unit that is provided in at least a portion of a wall of the vacuum tank and has a lattice-shaped convex portion with respect to the wall, and to which the evaporated substance is adhered.

According to the evaporation apparatus of the fourth aspect of the invention, similarly to the evaporation apparatus according to any one of the first, second, and third aspects of the invention, the substance evaporated from the evaporation source is deposited on the substrate in the vacuum tank.

In particular, according to the above-described configuration, the evaporated substance adhering unit that has the lattice-shaped convex portion with respect to the wall and to which the evaporated substance is adhered is provided in at least a portion of the wall of the vacuum tank. That is, for example, when the evaporation source is placed on the lower side of the vacuum tank and the substrate is placed on the upper side thereof, the lattice-shaped convex portion is provided above the evaporation source at the side portion of the wall of the vacuum tank. The lattice-shaped convex portion is formed by, for example, arranging a plurality of metal lines, which are formed of a metal, such as aluminum or the like, and have a diameter of approximately 1 mm, on the wall to form a lattice of approximately 2 mm square. Alternatively, a mesh that is formed from a plurality of metal lines formed of a metal, such as aluminum or the like, may be attached to the wall. Further, a plurality of metal rods or metal plates that are combined in a lattice shape may be attached to the wall. In addition, a metal plate having a plurality of openings arranged in a lattice shape may be attached to the wall. Moreover, the lattice-shaped convex portion may be provided in a deposition preventing plate that is provided at the wall of the vacuum tank and to which the evaporated substance is adhered. That is, the term ‘evaporated substance adhering unit’ according to the aspects denotes a concept including a deposition preventing plate having a lattice-shaped convex portion.

According to the evaporation apparatus of the fourth aspect of the invention, with the evaporated substance adhering unit that has the lattice-shaped convex portion with respect to the wall, similarly to the evaporation apparatus according to the first aspect of the invention, the amount of the substance evaporated from the evaporation source that can be adhered to the wall of the vacuum tank can be increased. Therefore, the amount of particles produced due to the adhered substance being separated from the wall in the vacuum tank can be reduced. In addition, the directionality of the deposited film to be deposited on the substrate can be improved.

In the evaporation apparatus according to the third or fourth aspect of the invention, the evaporated substance adhering unit is disposed to be at least partially spaced at a predetermined gap from the wall.

With this configuration, the evaporated substance can be adhered between the evaporated substance adhering unit and the wall. Accordingly, with the evaporated substance adhering unit, trap efficiency for trapping the evaporated substance can be increased. Therefore, the amount of particles produced due to the adhered substance can be further reduced, and the directionality of the deposited film to be deposited on the substrate can be further improved.

According to a fifth aspect of the invention, an evaporation method includes depositing an evaporated substance on a substrate using the evaporation apparatus (including the above-described configurations) according to any one of the first to fourth aspects of the invention so as to form a deposited film.

According to the evaporation method of the fifth aspect of the invention, in the forming of the deposited film, the amount of particles produced due to the adhered substance being separated from the wall is reduced, and the amount of the evaporated substance that rebounds from the wall is reduced. Therefore, in the forming of the deposited film, the deposited film can be uniformly deposited on the entire surface or a relatively wide region of the substrate.

According to a sixth aspect of the invention, a method of manufacturing an electro-optical device includes forming an inorganic alignment film for an electro-optical device on a substrate using the evaporation apparatus according to any one of the first to fourth aspects of the invention with an inorganic material as an evaporation source.

According to the method of manufacturing an electro-optical device of the sixth aspect of the invention, in a manufacturing process of an electro-optical device, such as a liquid crystal display that can perform high-quality image display and can be user for various electronic apparatuses, such as a projection-type display device, a television, a cellular phone, an electronic organizer, a word processor, a view-finder-type or monitor-direct-view-type video tape recorder, a workstation, a video phone, a POS terminal, or a touch panel, the inorganic alignment film can be uniformly deposited on the entire region or a relatively wide region of the substrate.

According to a seventh aspect of the invention, a film-forming apparatus includes a film-forming unit that deposits released particles from a target on a substrate so as to form a thin film on the substrate, a shield member that is provided between the target and the substrate and has an opening through which the released particles pass, and a released particle adhering unit that is provided in at least a portion of a surface of the shield member and has a plurality of protrusions protruding from the surface, and to which the released particles are adhered.

According to the film-forming apparatus of the seventh aspect of the invention, the thin film is formed on the substrate by the film-forming unit, for example, using a sputtering method. That is, the released particles as sputter particles from the target (that is, a base material of the thin film to be formed) are deposited on the substrate by the film-forming unit.

The shield member is provided between the target and the substrate and has the opening through which the released particles pass. For this reason, with the shield member, the released particles can be prevented from being deposited on the surface of the substrate from an unnecessary direction. Moreover, the shield member may be provided between the target and the substrate and extend from a main body, in which the opening is formed, to cover the periphery of the substrate.

In particular, according to the above-described configuration, the released particle adhering unit that has the plurality of protrusions protruding from the surface of the shield member is provided in at least a portion of the surface of the shield member. The plurality of protrusions are provided to protrude in a direction toward the substrate in a portion of the surface of the shield member facing the substrate, and to protrude in a direction toward the target in a portion of the surface of the shield member facing the target. The plurality of protrusions each have a width and a thickness of approximately several mm and protrude in the direction toward the substrate or the target in eave shapes by approximately several mm. The plurality of protrusions are arranged in a lattice shape or stripe shapes at the surface of the shield member.

With the released particle adhering unit, when the released particles from the target are adhered to the surface of the shield member as an adhered substance, the amount of the adhered substance held on the surface (that is, the amount of the released particles that can be adhered to the surface) can be increased. Specifically, a time for which the released particles are held on the surface can be increased. Usually, upon film-forming by the film-forming unit, if the amount of the released particles adhered to the surface of the shield member is increased, the released particles may not be held on the surface. However, according to the above-described configuration, the adhered substance can be prevented from being separated from the surface of the shield member. Therefore, the amount of particles produced due to the adhered substance being separated from the shield member can be reduced. As a result, the quality of the thin film to be formed on the substrate can be improved.

According to an eighth aspect of the invention, a film-forming apparatus includes a film-forming unit that deposits released particles from a target on a substrate so as to form a thin film on the substrate, a shield member that is provided between the target and the substrate and has an opening through which the released particles pass, and a released particle adhering unit that is provided in at least a portion of a surface of the shield member and has a plurality of concave portions to be depressed from the surface, and to which the released particles are adhered.

According to the film-forming apparatus of the eighth aspect of the invention, similarly to the film-forming apparatus according to the seventh aspect of the invention, the thin film is formed on the substrate by the film-forming unit, for example, using a sputtering method.

In particular, according to the above-described configuration, the released particle adhering unit that has the plurality of concave portions to be depressed from the surface is provided in at least a portion of the surface of the shield member. The plurality of concave portions are provided to be depressed along a direction toward the substrate in a portion of the surface of the shield member facing the substrate, and are provided to be depressed along a direction toward the target in a portion of the surface of the shield member facing the target. The plurality of concave portions each have a width and a thickness of approximately several mm, and are depressed along the direction toward the substrate or the target by approximately several mm. The plurality of concave portions are arranged in a lattice shape or stripe shapes at the surface of the shield member.

With the released particle adhering unit, similarly to the film-forming apparatus according to the seventh aspect of the invention, when the released particles from the target are adhered to the surface of the shield member as an adhered substance, the amount of the adhered substance held on the surface can be increased. Therefore, the quality of the thin film to be formed on the substrate can be improved.

According to a ninth aspect of the invention, a film-forming apparatus includes a film-forming unit that deposits released particles from a target on a substrate so as to form a thin film on the substrate, a shield member that is provided between the target and the substrate and has an opening through which the released particles pass, and a released particle adhering unit that is provided in at least a portion of a surface of the shield member and has a mesh-shaped concavo-convex portion with respect to the surface, and to which the released particles are adhered.

According to the film-forming apparatus of the ninth aspect of the invention, similarly to the film-forming apparatus according to the seventh aspect of the invention, the thin film is formed on the substrate by film-forming unit, for example, using a sputtering method.

In particular, according to the above-described configuration, the released particle adhering unit that has the mesh-shaped concavo-convex portion with respect to the surface is provided in at least a portion of the surface of the shield member. With the released particle adhering unit, similarly to the film-forming apparatus according to the seventh aspect of the invention, when the released particles from the target are adhered to the surface of the shield member as an adhered substance, the amount of the adhered substance held on the surface can be increased.

According to a tenth aspect of the invention, a film-forming apparatus includes a film-forming unit that deposits released particles from a target on a substrate so as to form a thin film on the substrate, a shield member that is provided between the target and the substrate and has an opening through which the released particles pass, and a released particle adhering unit that is provided in at least a portion of a surface of the shield member and has a lattice-shaped convex portion with respect to the surface, and to which the released particles are adhered.

According to the film-forming apparatus of the tenth aspect of the invention, similarly to the film-forming apparatus according to the seventh aspect of the invention, the thin film is formed on the substrate by the film-forming unit, for example, using a sputtering method.

In particular, according to the above-described configuration, the released particle adhering unit that has the lattice-shaped convex portion with respect to the surface is provided in at least a portion of the surface of the shield member. With the released particle adhering unit, similarly to the film-forming apparatus according to the seventh aspect of the invention, when the released particles from the target are adhered to the surface of the shield member as an adhered substance, the amount of the adhered substance held on the surface can be increased.

The advantages and effects of the invention will be apparent from the following preferred embodiments.

### BRIEF DESCRIPTION OF THE DRAWINGS

The invention will be described with reference to the accompanying drawings, wherein like numbers reference like elements.

FIG. 1 is a schematic cross-sectional view showing the configuration of an evaporation apparatus according to a first embodiment.

FIG. 2 is a perspective view showing a plurality of eave portions according to the first embodiment.

FIG. 3 is a plan view showing a plurality of eave portions according to the first embodiment.

FIG. 4 is an enlarged cross-sectional view of a portion C1 in FIG. 1.

FIG. 5 is a perspective view of a first modification, which corresponds to FIG. 2.

FIG. 6 is a perspective view of the second embodiment, which corresponds to FIG. 2.

FIG. 7 is an enlarged cross-sectional view of the second embodiment, which corresponds to FIG. 4.

FIG. 8 is a perspective view of a second modification, which corresponds to FIG. 6.

FIG. 9 is a plan view of the third embodiment, which corresponds to FIG. 3.

FIG. 10 is a cross-sectional view taken along the line X-X of FIG. 9.

FIG. 11 is a process view showing a flow of a method of manufacturing an electro-optical device using the evaporation apparatus according to the first embodiment.

FIG. 12 is a schematic side cross-sectional view showing the configuration of a sputtering apparatus according to an embodiment.

### DESCRIPTION OF EXEMPLARY EMBODIMENTS

Hereinafter, embodiments of the invention will be described with reference to the drawings.

### First Embodiment

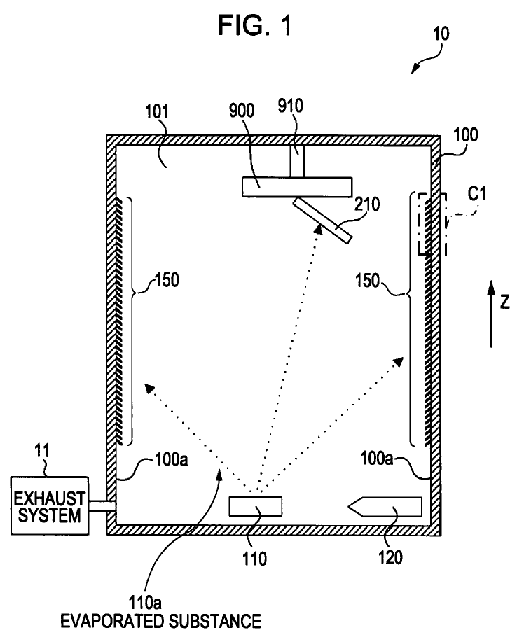

An evaporation apparatus according to a first embodiment of the invention will be described with reference to FIGS. 1 to 4.

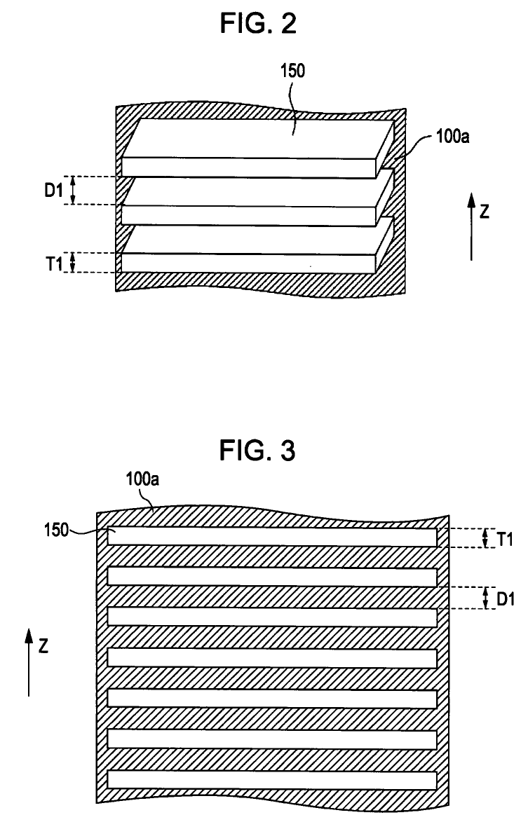

First, the overall configuration of the evaporation apparatus according to this embodiment will be described with reference to FIG. 1. FIG. 1 is a schematic side cross-sectional view showing the configuration of the evaporation apparatus according to this embodiment. Moreover, in FIG. 1, the scale of each component has been adjusted to have a recognizable size. The same is applied to FIGS. 2 to 10.

In FIG. 1, the evaporation apparatus 10 includes a chamber 100.

The chamber 100 is an example of the ‘vacuum tank’ according to the aspects of the invention, and is formed of, for example, a metal, such as aluminum, or steel, such as stainless steel.

The inner wall of the chamber 100 defines a space 101 inside the chamber 100. A target 110, an electron beam irradiation system 120, and a substrate 210 are disposed in the space 101. Although not shown in the drawings, a jig is provided for holding the target 110. Moreover, a portion of a side surface of the chamber 100 is connected to an exhaust system 11. A vacuum state in the space 101 can be maintained by discharging a gas in the space 101 outside the chamber 100. Further, the exhaust system 11 is a vacuum exhaust system including a rotary pump, which is a sub exhaust device (for example, used for initial exhaustion), and a turbomolecular pump, which is a main exhaust device (for example, used for main exhaustion).

The target 110 is, for example, a bulk inorganic material, which is a material for forming an inorganic alignment film in an electro-optical device, such as a liquid crystal device. The target 110 is placed on a crucible (not shown). Moreover, the target 110 is an example of the ‘evaporation source’ according to the aspects of the invention.

The electron beam irradiation system 120 includes a filament, a part of a power supply system, a cooling water system, a control system, and various wiring members. An electron beam can be generated from the filament. Moreover, the electron beam irradiation system 120 is an example of the ‘evaporation unit’ according to the aspects of the invention.

The substrate 210 is a low-temperature polysilicon substrate that can be suitably used for an electro-optical device, such as a liquid crystal device.

The substrate 210 is held with a jig 900 in the space 101 to be obliquely disposed at a predetermined angle with respect to a side portion 100a of the chamber 100. The jig 900 is fixed to a top surface of the chamber 100 by means of a support 910.

In this embodiment, particularly, a plurality of eave portions 150, which are an example of ‘a plurality of protrusions’ according to the aspects of the invention, are provided at the side portion 100a of the chamber 100. As described below in detail, the plurality of eave portions 150 protrude in a direction toward the target 110 (that is, the jig holding the target 110) at an angle relative to a direction normal to the side portion 100a. The angle of the eave portions 150 can be set within a range of angles for all possible imaginary lines extending from all positions of the jig that holds the target 110 to the portion of side portion 100a where the eave portions 150 are provided.

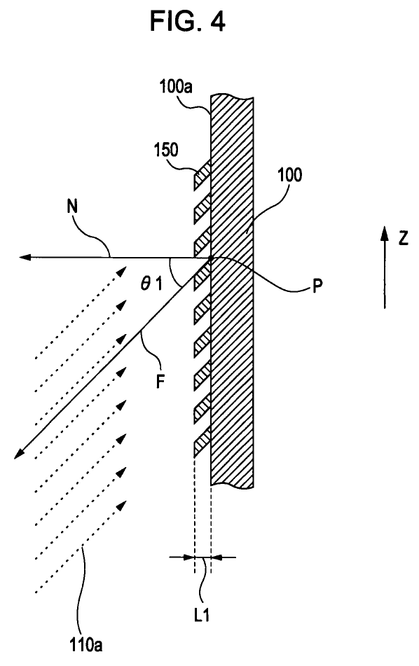

Next, the configuration of the plurality of eave portions of the evaporation apparatus according to this embodiment will be described in detail with reference to FIGS. 2 to 4, in addition to FIG. 1. FIG. 2 is a perspective view showing the plurality of eave portions according to this embodiment. FIG. 3 is a plan view showing the plurality of eave portions according to this embodiment. FIG. 4 is an enlarged cross-sectional view of a portion C1 shown in FIG. 1.

As shown in FIGS. 1 and 2, the plurality of eave portions 150 are provided above the target 110 at the side portion 100a of the chamber 100 to protrude in a direction toward the target 110 (that is, an obliquely downward direction in FIG. 1).

Each of the plurality of eave portions 150 is formed of a metal, such as aluminum, stainless steel, or copper, and is fixed to the side portion 100a.

As shown in FIGS. 2 and 3, the plurality of eave portions 150 are formed in stripe shapes at the side portion 100a along the bottom surface (that is, along a direction crossing a direction normal to the bottom surface (that is, a Z direction) to have a thickness T1 and an interval D1 of approximately 1 to 2 mm. That is, the plurality of eave portions 150 are formed in multiple lines along the bottom surface at the side portion 100a.

As shown in FIG. 4, the plurality of eave portions 150 are formed to protrude from the side portion 100a by a length L1 along a direction (that is, a direction indicated by an arrow F in FIG. 4) shifted downward from the direction normal to the side portion 100a of the chamber 100 (that is, a direction indicated by an arrow N in FIG. 4) at an angle θ1.

The plurality of eave portions 150 are formed so as to have the length L1 of approximately 1 to 2 mm.

The angle θ1 is set to an angle between the direction normal to the side portion 100a of the chamber 100 (that is, the direction indicated by the arrow N in FIG. 4) and a direction from the side portion 100a toward the target 110. In this embodiment, the angle θ1 is set to an angle between the direction normal to the side portion 100a of the chamber 100 (that is, the direction indicated by the arrow N in FIG. 4) and a direction from an arbitrary point P on the side portion 100a toward the target 110. Moreover, the angle θ1 may be set to an average of angles between the direction normal to the side portion 100a of the chamber 100 (that is, the direction indicated by the arrow N in FIG. 4) and directions from individual points on the side portion 100a toward the target 110. Alternatively, the angle θ1 may vary with respect to the plurality of eave portions 150.

Moreover, when a deposition preventing plate to which an evaporated substance 110a is adhered is provided at the side portion 100a of the chamber 100, the plurality of eave portions 150 may be provided in the deposition preventing plate. Further, the plurality of eave portions may be provided in at least a portion of the bottom surface of the chamber 100 or an opposing top surface thereof.

Next, the operation of the evaporation apparatus according to this embodiment will be described with reference to FIGS. 1 to 4.

In FIG. 1, during an evaporation process performed by the evaporation apparatus 10, an electron beam is emitted from the electron beam irradiation system 120 and then irradiated onto the target 110. The target 110 onto which the electron beam is irradiated is heated and a part thereof is evaporated. The evaporated substance 110a evaporated from the target is deposited on the substrate 210 that is disposed to obliquely face the target 110.

At this time, a part of the evaporated substance 110a flies toward the side portion 100a of the chamber 100, and then the evaporated substance 110a is adhered to the side portion 100a as an adhered substance.

In a case where appropriate measures are not taken, if the amount of the adhered substance adhered to the side portion 100a increases, the adhered substance becomes separated from the side portion 100a, and particles may be produced. The particles contaminate the space 101 in the chamber 100, which causes degradation of quality of a deposited film to be deposited on the substrate 210.

In addition, if the amount of the adhered substance adhered to the side portion 100a increases, the evaporated substance 110a becomes rarely attached to the side portion 100a. Then, the amount of the evaporated substance 110a that rebounds from the side portion 100a and goes toward the substrate 210 may be increased. That is, the amount of the evaporated substance 110a that reaches the side portion 100a but rebounds from the side portion 100a, and goes toward the substrate 210 in a direction different from a predetermined direction (that is, a direction from the target 110 toward the substrate 210) is increased. For this reason, directionality of the deposited film to be formed on the substrate 210 may be degraded.

In contrast, in this embodiment, as described above with reference to FIGS. 1 to 4, the plurality of eave portions 150 that protrude in the direction toward the target 110 (that is, the direction indicated by the arrow F in FIG. 4) at an angle relative to the direction normal to the side portion 100a (that is, the direction indicated by the arrow N in FIG. 4) are provided in at least a portion of the side portion 100a of the chamber 100. Accordingly, when the evaporated substance 110a evaporated from the target 110 is adhered to the side portion 100a of the chamber 100 as the adhered substance, the amount of the adhered substance held on the side portion 100a (that is, the amount of the evaporated substance 110a that can be adhered to the side portion 100a) may be increased.

More specifically, with the plurality of eave portions 150 provided at the side portion 100a, the total surface area of the side portion 100a where the evaporated substance 110a can be adhered can be increased. Then, the amount of the evaporated substance 110a that is adhered to the plurality of eave portions 150 at the side portion 100a can be increased. That is, the amount of the adhered substance held on the side portion 100a can be increased. Accordingly, a time for which the adhered substance is held on the side portion 100a can be increased. Therefore, during the evaporation process, when the amount of the evaporated substance 110a adhered to the side portion 100a of the chamber 100 as the adhered substance increases, the adhered substance can be suppressed or prevented from being separated from the side portion 100a. As a result, the amount of particles produced due to the adhered substance being separated from the side portion 100a in the chamber 100 can be reduced, and thus the quality of the deposited film to be deposited on the substrate 210 can be improved.

In addition, as shown in FIG. 4, the plurality of eave portions 150 protrude in a direction toward the target 110 at an angle relative to the direction normal to the side portion 100a. Accordingly, the evaporated substance 110a easily enters between the lower surface of each of the plurality of eave portions 150 and the side portion 100a, and then the evaporated substance 110a that rebounds from the side portion 100a and goes toward the upper side can be adhered to the plurality of eave portions 150. That is, the amount of the evaporated substance 110a that rebounds from the side portion 100a of the chamber 100 and goes toward the substrate 210 can be reduced or the evaporated substance 110a can be prevented from rebounding from the side portion 100a of the chamber 100 and going toward the substrate 210. Specifically, the amount of the evaporated substance 110a that goes toward the substrate 210 in a direction different from the predetermined direction can be reduced or the evaporated substance 110a can be prevented from going toward the substrate 210 in a direction different from the predetermined direction. Therefore, the directionality of the deposited film to be deposited on the substrate 210, for example, an inorganic alignment film having a predetermined pretilt angle, can be increased. That is, the deposited film can be almost or completely uniformly formed on the entire region or a relatively wide region of the surface of the substrate 210.

As described above, according to the evaporation apparatus 10, with the plurality of eave portions 150 that protrude in the direction toward the target 110, the amount of the evaporated substance 110a evaporated from the target 110 that can be adhered to the side portion 100a of the chamber 100 can be increased. Accordingly, the amount of particles produced due to the adhered substance being separated from the side portion 100a in the chamber 100 can be reduced. In addition, the directionality of the deposited film to be deposited on the substrate 210 can be improved.

Moreover, according to the evaporation apparatus 10, since the amount of the evaporated substance 110a that can be adhered to the side portion 100a of the chamber 100 is increased, a frequency of a cleaning process for cleaning the side portion 100a can be reduced. Alternatively, when the plurality of eave portions 150 is provided in a deposition preventing plate, a frequency of a cleaning process for cleaning the deposition preventing plate or a frequency of replacement for replacing the deposition preventing plate can be reduced.

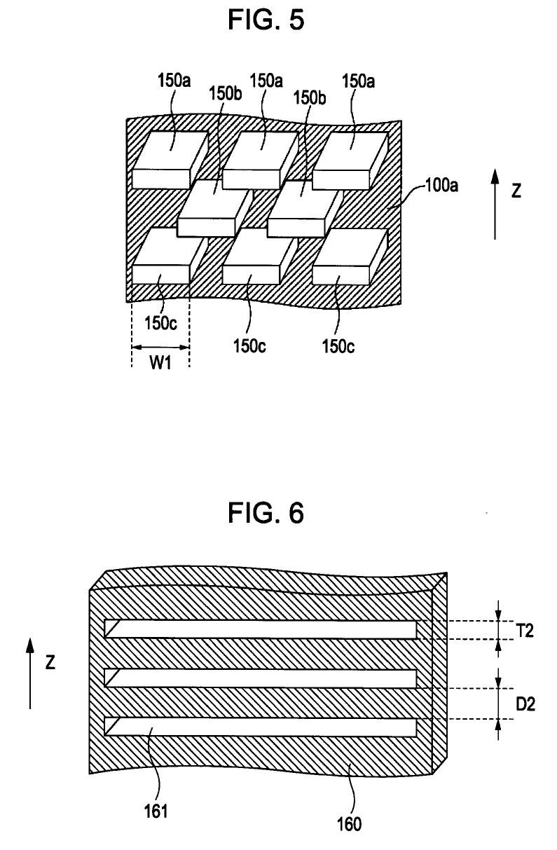

As shown in FIG. 5 as a modification, the plurality of eave portions 150 may be formed in multiple lines in a direction along the bottom surface (the left to right and right to left directions in FIG. 5) at the side portion 100a. FIG. 5 is a perspective view of a first modification of the invention, which corresponds to FIG. 2.

That is, the plurality of eave portions 150 may have multiple lines including a line of a plurality of eave portions 150a, a line of a plurality of eave portions 150b, and a line of a plurality of eave portions 150c. In this case, the plurality of eave portions 150 may be reduced in size or the arrangement interval thereof may become narrower. Then, the number of a plurality of eave portions 150 is increased at the side portion 100a. Accordingly, the total surface area of the plurality of eave portions 150 can be increased. Therefore, the amount of the evaporated substance 110a that is adhered to the plurality of eave portions 150 can be increased. Moreover, the width W1 of each of the plurality of eave portions 150 may be set to approximately 1 to 2 mm.

### Second Embodiment

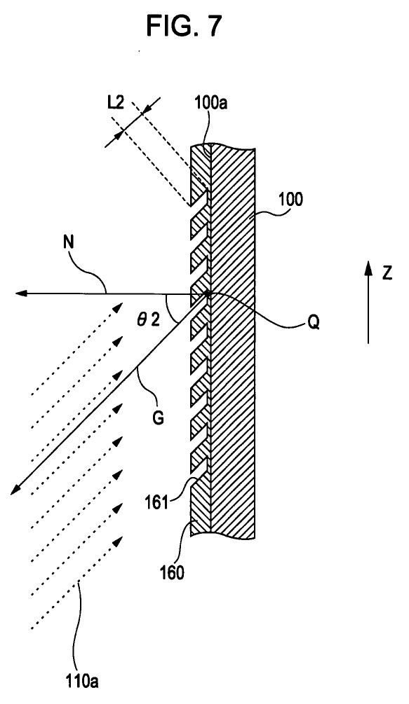

Next, an evaporation apparatus according to a second embodiment will be described with reference to FIGS. 6 and 7. FIG. 6 is a perspective view of the second embodiment, which corresponds to FIG. 2. FIG. 7 is an enlarged cross-sectional view of the second embodiment, which corresponds to FIG. 4. Moreover, in FIGS. 6 and 7, the same parts as those in the first embodiments shown in FIGS. 1 to 4 are represented by the same reference numerals, and the descriptions thereof will be omitted.

As shown in FIGS. 6 and 7, the evaporation apparatus according to this embodiment is different from the evaporation apparatus according to the above-described first embodiment in that, instead of the plurality of eave portions 150 of the first embodiment, an evaporated substance adhering plate 160 is provided at the side portion 100a of the chamber 100. Other parts are the same as those in the evaporation apparatus according to the above-described first embodiment.

As shown in FIGS. 6 and 7, a plurality of concave portions 161 are formed in the evaporated substance adhering plate 160, and the evaporated substance adhering plate 160 is disposed at the side portion 100a such that the plurality of concave portions 161 are depressed with respect to the inside of the chamber 100.

As shown in FIGS. 6 and 7, the plurality of concave portions 161 are formed to be depressed with respect to the target 110 along the direction toward the target 110 (that is, an obliquely downward direction in FIG. 7).

The evaporated substance adhering plate 160 is formed of a metal, such as aluminum, stainless steel, or copper, and is fixed to the side portion 100a.

As shown in FIG. 6, the plurality of concave portions 161 are formed in stripe shapes at the side portion 100a along the bottom surface (that is, along a direction crossing a Z direction as the direction normal to the bottom surface) to have a thickness T2 and an interval D2 of approximately 1 to 2 mm. That is, the plurality of concave portions 161 are formed at the side portion 100a in multiple lines along the bottom surface.

As shown in FIG. 7, the plurality of concave portions 161 are formed to be depressed with respect to the target 110 at a length L2 from the side portion 100a along a direction (that is, a direction indicated by an arrow G in FIG. 7) shifted downward with respect to the direction normal to the side portion 100a of the chamber 100 (that is, a direction indicated by an arrow N in FIG. 7) at an angle θ2.

The plurality of concave portions 150 are formed to have the length L2 of approximately 1 to 2 mm.

The angle θ2 is set to an angle between the direction normal to the side portion 100a of the chamber 100 (that is, the direction indicated by the arrow N in FIG. 7) and a direction from the side portion 100a toward the target 110. In this embodiment, the angle θ2 is set to an angle between the direction normal to the side portion 100a of the chamber 100 (that is, the direction indicated by the arrow N in FIG. 7) and a direction from an arbitrary point Q on the side portion 100a toward the target 110. Moreover, the angle θ2 may be set to an average of angles between the direction normal to the side portion 100a of the chamber 100 (that is, the direction indicated by the arrow N in FIG. 7) and directions from individual points on the side portion 100a toward the target 110. Alternatively, the angle θ2 may vary with respect to the plurality of concave portions 161.

Moreover, the plurality of concave portions 161 may be formed at the side portion 100a of the chamber 100. Further, the evaporated substance adhering plate may be provided in at least a portion of the bottom surface of the chamber 100 or an opposing top surface thereof.

In particular, in this embodiment, the evaporated substance adhering plate 160 having the above-described configuration is provided at the side portion 100a of the chamber 100. Accordingly, similarly to the evaporation apparatus according to the above-described first embodiment, when the evaporated substance 110a evaporated from the target 110 is adhered to the side portion 100a of the chamber 100 as an adhered substance, the amount of the adhered substance held on the side portion 100a (that is, the amount of the evaporated substance 110a that can be adhered to the side portion 100a) can be increased.

More specifically, with the plurality of concave portions 161 of the evaporated substance adhering plate 160 provided at the side portion 100a, the total surface area of the side portion 100a where the evaporated substance 110a can be attached can be increased. Accordingly, the amount of the evaporated substance 110a that is adhered to the plurality of concave portions 161 at the side portion 100a can be increased. That is, the amount of the adhered substance held on the side portion 100a can be increased.

Accordingly, a time for which the adhered substance is adhered on the side portion 100a can be increased. Therefore, during the evaporation process, when the amount of the evaporated substance 110a that is adhered to the side portion 100a of the chamber 100 as the adhered substance increases, the adhered substance can be suppressed or prevented from being separated from the side portion 100a. As a result, the amount of particles produced due to the adhered substance being separated from the side portion 100a in the chamber 100 can be reduced. Then, the quality of the deposited film to be deposited on the substrate 210 can be improved.

In addition, as shown in FIG. 7, the plurality of concave portions 161 are depressed with respect to the target 110 in the direction toward the target 110 at an angle relative to the direction normal to the side portion 100a. Accordingly, the evaporated substance 110a easily enters the plurality of concave portions 161, and thus the evaporated substance 110a that rebounds from the plurality of concave portions 161 can be adhered to the plurality of concave portions 161. That is, the amount of the evaporated substance 110a that rebounds from the side portion 100a of the chamber 100 and goes toward the substrate 210 can be reduced or the evaporated substance 110a can be prevented from rebounding from the side portion 100a of the chamber 100 and going toward the substrate 210. Specifically, the amount of the evaporated substance 110a that goes toward the substrate 210 can be reduced or the evaporated substance 110a can be prevented from going toward the substrate 210. Therefore, the directionality of the deposited film to be deposited on the substrate 210, for example, an inorganic alignment film having a predetermined pretilt angle, can be improved. That is, the deposited film can be almost or completely uniformly on the entire region or a relatively wide region of the surface of the substrate 210.

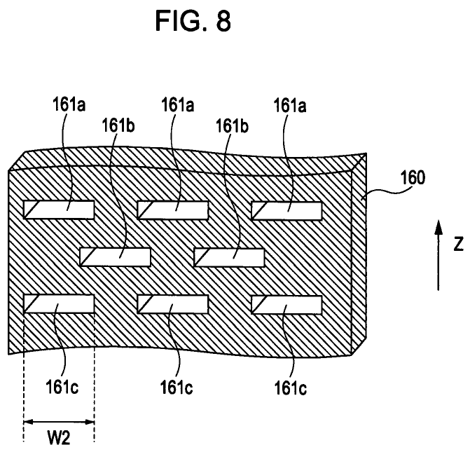

As shown in FIG. 8 as a modification, the plurality of concave portions 161 of the evaporated substance adhering plate 160 may be formed in multiple lines along the bottom surface (a left and right direction in FIG. 8). FIG. 8 is a perspective view of a second modification of the invention, which corresponds to FIG. 6.

That is, the plurality of concave portions 161 may have multiple lines of a line of a plurality of concave portions 161a, a line of a plurality of concave portions 161b, and a line of a plurality of concave portions 161c. In this case, the plurality of concave portions 161 may be reduced in size or the arrangement interval may become narrower. Then, the number of the plurality of concave portions 161 in the evaporated substance adhering plate 160 that is disposed at the side portion 100a is increased. Accordingly, the total surface area of the plurality of concave portions 161 can be increased. Therefore, the amount of the evaporated substance 110a that is adhered to the evaporated substance adhering plate 160 (in particular, the plurality of concave portions 161) can be increased. Moreover, the width W2 of each of the plurality of concave portions 161 may be set to approximately 1 to 2 mm.

### Third Embodiment

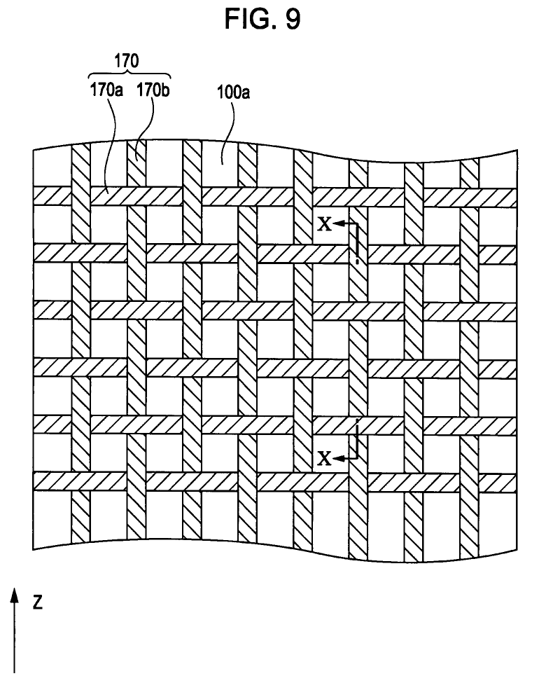

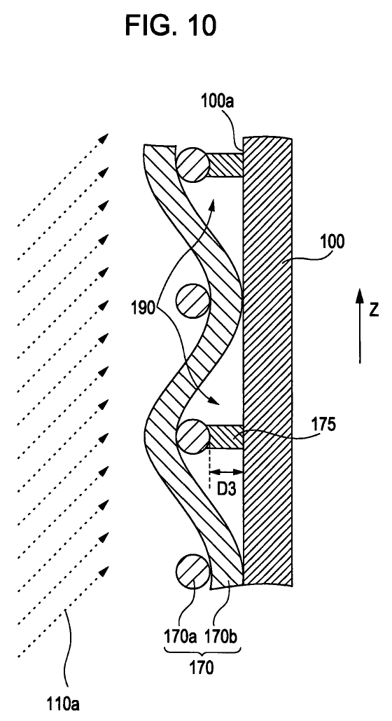

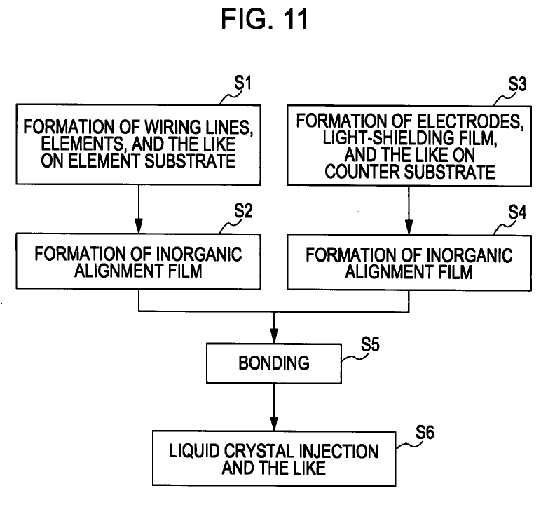

Next, an evaporation apparatus according to a third embodiment will be described with reference to FIGS. 9 and 10. FIG. 9 is a plan view of the third embodiment, which corresponds to FIG. 3. FIG. 10 is a cross-sectional view taken along the line X-X of FIG. 9. Moreover, in FIGS. 9 and 10, the same parts as those in the first embodiment shown in FIGS. 1 to 4 are represented by the same reference numerals, and the descriptions thereof will be omitted.

As shown in FIGS. 9 and 10, the evaporation apparatus according to this embodiment is different from the evaporation apparatus according to the above-described first embodiment in that, instead of the plurality of eave portions 150 in the first embodiment, an evaporated substance adhering mesh 170 is provided at the side portion 100a of the chamber 100. Other parts are the same as those in the evaporation apparatus according to the above-described first embodiment.

As shown in FIGS. 9 and 10, the evaporated substance adhering mesh 170 is a metal mesh formed by weaving metal lines 170a and 170b formed of a metal, such as aluminum, stainless steel, or copper, and is fixed to the side portion 100a. The widths W3 and W4 of the metal lines 170a and 170b are approximately 1 mm. The metal lines 170a and 170b are arranged at an interval of approximately 2 mm. That is, the evaporated substance adhering mesh 170 are formed by weaving the metal lines 170a and 170b to define a mesh or a lattice of approximately 2 mm square.

As shown in FIG. 10, the evaporated substance adhering mesh 170 is fixed to the side portion 100a by a support 175 disposed for one metal line 170a (or for one metal line 170b), and is disposed to be partially spaced at a gap D3 from the side portion 100a. Accordingly, a space 190 is partially formed between the evaporated substance adhering mesh 170 and the side portion 100a. Moreover, the interval D3 is set to approximately 1 to 2 mm.

In particular, in this embodiment, the evaporated substance adhering mesh 170 having the above-described configuration is provided at the side portion 100a of the chamber 100. Accordingly, similarly to the evaporation apparatus according to the above-described first embodiment, when the evaporated substance 110a evaporated from the target 110 is adhered to the side portion 100a of the chamber 100 as an adhered substance, the amount of the adhered substance held on the side portion 100a (that is, the amount of the evaporated substance 110a that can be adhered to the side portion 100a) can be increased.

More specifically, with the mesh by the metal lines 170a and 170b constituting the evaporated substance adhering mesh 170 provided at the side portion 100a, the total surface area of the side portion 100a where the evaporated substance 110a can be adhered can be increased. Accordingly, the amount of the evaporated substance 110a that is adhered to the metal lines 170a and 170b at the side portion 100a can be increased. That is, the amount of the adhered substance held on the side portion 100a can be increased.

Accordingly, a time for which the adhered substance is held on the side portion 100a can be increased. Therefore, during the evaporation process, when the amount of the evaporated substance 110a that is adhered to the side portion 100a of the chamber 100 as the adhered substance increases, the adhered substance can be suppressed or prevented from being separated from the side portion 100a. Therefore, the amount of particles produced due to the adhered substance being separated from the side portion 100a in the chamber 100 can be reduced. As a result, the quality of the deposited film to be deposited on the substrate 210 can be improved.

Referring to FIG. 10, in this embodiment, as described above, the evaporated substance adhering mesh 170 is disposed to be partially spaced at the gap D3 from the side portion 100a. Accordingly, the evaporated substance 110a can be adhered between the evaporated substance adhering mesh 170 and the side portion 100a. That is, the evaporated substance 110a that passes through the evaporated substance adhering mesh 170 and reaches the space 190 or the evaporated substance 110a that rebounds from the side portion 100a can be adhered to a side of the evaporated substance adhering mesh 170 facing the side portion 100a. Therefore, with the evaporated substance adhering mesh 170, trap efficiency for trapping the evaporated substance 110a can be increased. As a result, the amount of particles produced due to the adhered substance can be further reduced, and the directionality of the deposited film to be deposited on the substrate can be further improved.

Moreover, although the evaporated substance adhering mesh 170 that is formed by weaving the metal lines is provided at the side portion 100a, a plurality of metal rods or metal plates that are combined in a lattice shape may be provided at the side portion 100a. Alternatively, a metal plate having a plurality of openings arranged in a lattice shape may be provided at the side portion 100a. In these cases, similarly to a case where the evaporated substance adhering mesh 170 is provided at the side portion 100a, with the plurality of metal rods or metal plates that are combined in a lattice shape or with the metal plate having the plurality of openings arranged in a lattice shape, trap efficiency for trapping the evaporated substance 110a can be increased.

### Method of Manufacturing Electro-Optical Device

Next, a method of manufacturing an electro-optical device using the evaporation apparatus according to this embodiment will be described with reference to FIG. 11. Here, a liquid crystal device that has an element substrate and a counter substrate as a pair of substrates, and liquid crystal as an electro-optical material interposed between the two substrates is exemplified as an example of an electro-optical device. FIG. 11 is a process view showing a flow of manufacturing.

In FIG. 11, first, various wiring lines, various electronic elements, various electrodes, various internal circuits, and the like are appropriately formed on the element substrate by an existing thin film forming technology or a patterning technology according to models to be manufactured (Step S1). Thereafter, an inorganic alignment film having a predetermined pretilt angle is formed on a surface of the element substrate facing the counter substrate by oblique evaporation using evaporation apparatus 10 according to the above-described embodiment (Step S2).

Further, various electrodes, various light-shielding films, various color filters, various microlens, and the like are formed on the counter substrate by an existing thin film forming technology or a patterning technology according to models to be manufactured (Step S3). Thereafter, an inorganic alignment film having a predetermined pretilt angle is formed on a surface of the counter substrate facing the element substrate by oblique evaporation using the evaporation apparatus 10 according to the above-described embodiment (Step S4).

Thereafter, the pair of the element substrate and the counter substrate, on which the inorganic alignment films are respectively formed, are bonded to each other using a sealant formed of ultraviolet curable resin or thermosetting resin such that both inorganic alignment films face each other (Step S5). Next, liquid crystal is injected between the bonded substrates using vacuum absorption. Subsequently, sealing by a sealing material, such as an adhesive, cleaning, and test are performed (Step S6).

In such a manner, the manufacturing of the liquid crystal device having the inorganic alignment films formed using oblique evaporation by the evaporation apparatus 10 according to the above-described embodiment is completed. As such, since the inorganic alignment films are formed using the evaporation apparatus 10 according to the above-described embodiment, according to this manufacturing method, the inorganic alignment film can be uniformly deposited on the entire region or a relatively wide region of the surface of the substrate.

### Film-Forming Apparatus

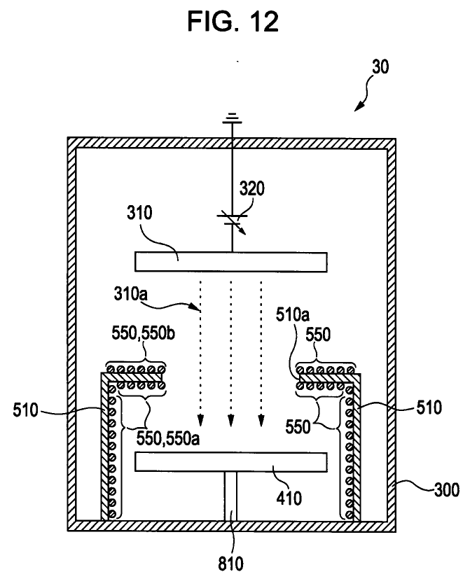

A film-forming apparatus according to this embodiment will be described with reference to FIG. 12. In the following description, a sputtering apparatus is exemplified as an example of the film-forming apparatus according to the invention.

FIG. 12 is a schematic side cross-sectional view showing the configuration of a sputtering apparatus according to this embodiment. Moreover, in FIG. 12, the scale of each part has been adjusted to have a recognizable size.

In FIG. 12, the sputtering apparatus 30 according to this embodiment includes a chamber 300.

A target 310, a power supply system 320, and a wafer 410 are disposed in the chamber 300. Moreover, the target 310 is an example of the ‘target’ according to the aspects of the invention, the power supply system 320 is an example of the ‘film-forming unit’ according to the aspects of the invention, and the wafer 410 is an example of the ‘substrate’ according to the aspects of the invention. Further, the power supply system 320 may be disposed outside the chamber 300.

The target 310 is a base material of a thin film that is to be formed on the wafer 410, such as a silicon wafer. The target 310 and the wafer 410 are disposed to face each other at a predetermined gap. The wafer 410 is fixed to the top surface of the chamber 300 by a support 810.

During the operation of the sputtering apparatus 30, for example, the chamber 300 is vacuumized through an exhaust pipe (not shown), an Ar gas is introduced into the chamber 300 through a gas introduction pipe (not shown) at a predetermined flow rate, and a voltage is applied between the wafer 410 and the target 310 (that is, between an electrode provided on the wafer 410 side and an electrode provided on the target 310 side) by the power supply system 320. Then, Ar ions that are accelerated within generated plasma sputters against the surface of the target 310, and sputter particles 310a are deposited on the wafer 410, thereby forming a thin film. Moreover, the sputter particles 310a are an example of the ‘released particles’ according to the aspects of the invention.

In addition, a shield member 510 is provided in the chamber 300. The shield member 510 is provided to cover the wafer 410 from the target 310 side and has an opening 510a through which the sputter particles 310a from the target 310 progress toward wafer 410. For this reason, with the shield member 510, the sputter particles 310a can be suppressed from being deposited from an unnecessary direction with respect to the wafer 410.

In particular, in this embodiment, a sputter particle adhering portion 550 as an example of the ‘released particle adhering unit’ according to the aspects of the invention is provided at the surface of the shield member 510. The sputter particle adhering portion 550 (that is, sputter particle adhering portions 550a and 550b) is a metal mesh having the same configuration as the evaporated substance adhering mesh 170 in the evaporation apparatus according to the above-described third embodiment described with reference to FIGS. 9 and 10, and is fixed to the surface of the shield member 510. The sputter particle adhering portion 550a is provided in a portion of the surface of the shield member 510 facing the wafer 410, and the sputter particle adhering portion 550b is provided in a portion of the surface of the shield member 510 facing the target 310. Accordingly, when the sputter particles 310a from the target 310 are adhered to the surface of the shield member 510 as an adhered substance, the amount of the adhered substance held on the surface can be increased. That is, a time for which the sputter particles 310a are held on the surface of the shield member 510 can be increased. Therefore, upon film-forming by the sputtering apparatus 30, when the amount of the sputter particles 310a adhered to the surface of the shield member 510 increases, the adhered substance can be suppressed or prevented from being separated from the surface of the shield member 510. As a result, the amount of particles produced due to the adhered substance being separated from the shield member 510 can be reduced. Then, the quality of the thin film to be deposited on the wafer 410 can be improved. In addition, a cycle at which the sputter particles 310a shield member 510 need to be removed can be extended. That is, a maintenance cycle of the sputtering apparatus 30 can be extended.

Here, the sputter particle adhering portion 550 may be a plurality of eave portions having the same configuration as the plurality of eave portions 150 in the evaporation apparatus according to the above-described first embodiment described with reference to FIGS. 1 to 5. More specifically, for example, the sputter particle adhering portion 550a may be provided as a plurality of eave portions that protrude in a direction toward the wafer 410, and the sputter particle adhering portion 550b may be provided as a plurality of eave portions that protrude in a direction toward the target 310. In this case, a time for which the sputter particles 310a are held on the surface of the shield member 510 can be increased.

Alternatively, the sputter particle adhering portion 550 may be a sputter particle adhering plate having the same configuration as the evaporated substance adhering plate 160 in the evaporation apparatus according to the above-described second embodiment described with reference to FIGS. 6 and 7. More specifically, for example, the sputter particle adhering portion 550a may be provided as a sputter particle adhering plate having a plurality of concave portions to be depressed along a direction toward the wafer 410, and the sputter particle adhering portion 550b may be provided as a sputter particle adhering plate having a plurality of concave portions to be depressed in a direction toward the target 310. In this case, a time for which the sputter particles 310a are held on the surface of the shield member 510 can be increased. Moreover, the sputter particle adhering portion 550 may be provided by forming a plurality of concave portions in the shield member 510.

The invention is not limited to the above-described embodiments, but various modifications can be made without departing from the subject matter or spirit of the invention read on the appended claims and the specification. It should be understood that an evaporation apparatus, an evaporation method, a method of manufacturing an electro-optical device using the evaporation apparatus, and a film-forming apparatus that accompany the modifications still fall within the technical scope of the invention.

What is claimed is:

1. An evaporation apparatus comprising:
a deposition unit that deposits a substance to be evaporated from an evaporation source onto a substrate;
a vacuum tank that defines a space for placing the evaporation source and the substrate and maintains a vacuum state in the space; and
an evaporated substance adhering unit that is provided in at least a portion of a wall in the vacuum tank and has a plurality of protrusions protruding in a direction toward the evaporation source at an angle relative to a direction normal to the wall, and to which the evaporated substance is adhered.

2. The evaporation apparatus according to claim 1,
wherein the evaporation source is disposed at a bottom surface of the vacuum tank, and
the plurality of protrusions are arranged at a side portion of the wall in multiple lines along a direction crossing a direction normal to the bottom surface.

3. The evaporation apparatus according to claim 1,
wherein the evaporation source is disposed at a bottom surface of the vacuum tank, and
the plurality of protrusions are formed at a side portion of the wall to extend along a direction crossing a direction normal to the bottom surface.

4. The evaporation apparatus according to claim 2,
wherein the side portion of the wall is adjacent to the bottom surface.

5. An evaporation apparatus comprising:
an evaporation unit that deposits a substance to be evaporated from an evaporation source on a substrate;
a vacuum tank that defines a space for placing the substrate and the evaporation source and maintains a vacuum state in the space; and
an evaporated substance adhering unit that is provided in at least a portion of a wall of the vacuum tank and has a plurality of concave portions to be depressed with respect to the evaporation source in a direction toward the evaporation source at an angle relative to a direction normal to the wall, and to which the evaporated substance is adhered.

6. The evaporation apparatus according to claim 5,
wherein a space that is defined by an inner surface of each of the plurality of concave portions has a space extending along the direction toward the evaporation source.

7. The evaporation apparatus according to claim 5,
wherein the evaporation source is disposed at a bottom surface of the vacuum tank, and
the plurality of concave portions are arranged at a side portion of the wall of the vacuum tank in multiple lines along a direction crossing a direction normal to the bottom surface.

8. The evaporation apparatus according to claim 5,
wherein the evaporation source is disposed at a bottom surface of the vacuum tank, and
the plurality of concave portions are formed at a side portion of the wall of the vacuum tank to extend along a direction crossing a direction normal to the bottom surface.

9. The evaporation apparatus according to claim 7,
wherein the side portion of the wall is adjacent to the bottom surface.

10. An evaporation apparatus comprising:
an evaporation unit that deposits a substance to be evaporated from an evaporation source on a substrate;
a vacuum tank that defines a space for placing the substrate and the evaporation source and maintains a vacuum state in the space; and
an evaporated substance adhering unit that is provided in at least a portion of a wall of the vacuum tank and has a mesh-shaped concavo-convex portion with respect to the wall, and to which the evaporated substance is adhered.

11. An evaporation apparatus comprising:
an evaporation unit that deposits a substance to be evaporated from an evaporation source on a substrate;
a vacuum tank that defines a space for placing the substrate and the evaporation source and maintains a vacuum state in the space; and
an evaporated substance adhering unit that is provided in at least a portion of a wall of the vacuum tank and has a lattice-shaped convex portion with respect to the wall, and to which the evaporated substance is adhered.

12. The evaporation apparatus according to claim 10,
wherein the evaporated substance adhering unit is disposed to be at least partially spaced at a predetermined gap from the wall.

13. A film-forming apparatus comprising:
a film-forming unit that deposits released particles from a target on a substrate so as to form a thin film on the substrate;
a shield member that is provided between the target and the substrate and has an opening through which the released particles pass; and
a released particle adhering unit that is provided in at least a portion of a surface of the shield member and has a plurality of protrusions protruding from the surface, and to which the released particles are adhered.

14. A film-forming apparatus comprising:
a film-forming unit that deposits released particles from a target on a substrate so as to form a thin film on the substrate;
a shield member that is provided between the target and the substrate and has an opening through which the released particles pass; and
a released particle adhering unit that is provided in at least a portion of a surface of the shield member and has a plurality of concave portions to be depressed from the surface, and to which the released particles are adhered.

15. A film-forming apparatus comprising:
a film-forming unit that deposits released particles from a target on a substrate so as to form a thin film on the substrate;
a shield member that is provided between the target and the substrate and has an opening through which the released particles pass; and
a released particle adhering unit that is provided in at least a portion of a surface of the shield member and has a mesh-shaped concavo-convex portion with respect to the surface, and to which the released particles are adhered.

16. A film-forming apparatus comprising:
a film-forming unit that deposits released particles from a target on a substrate so as to form a thin film on the substrate;
a shield member that is provided between the target and the substrate and has an opening through which the released particles pass; and
a released particle adhering unit that is provided in at least a portion of a surface of the shield member and has a lattice-shaped convex portion with respect to the surface, and to which the released particles are adhered.

17. The evaporation apparatus according to claim 1, the evaporated substance adhering unit being provided at an angle within a range of angles of imaginary lines extending from a jig that holds the evaporation source to the wall.
